(19) United States
(12) Patent Application Publication
(10) Pub. No.: US 2016/0099134 A1
(43) Pub. Date: Apr. 7, 2016

(54) ARC EVAPORATION COATING SOURCE HAVING A PERMANENT MAGNET

(71) Applicant: PLANSEE SE, Reutte (AT)

(72) Inventors: MATTHIAS PERL, TANNHEIM (AT); PETER POLCIK, REUTTE (AT); CONRAD POLZER, WEINSTADT (DE); STEFAN SCHLICHTHERLE, EHRWALD (AT); GEORG STRAUSS, MUENSTER (AT)

(21) Appl. No.: 14/786,226

(22) PCT Filed: Apr. 17, 2014
(86) PCT No.: PCT/AT2014/000078

§ 371 Date: Oct. 22, 2015

(30) Foreign Application Priority Data
Apr. 22, 2013 (AT) GM 131/2013

(51) Int. Cl. H01J 37/34; C23C 14/35; C23C 14/34

(52) U.S. Cl. CPC H01J 37/3405; C23C 14/3407; H01J 37/3417; C23C 14/35

(57) ABSTRACT

An arc evaporation coating source includes a target made of a coating material to be vapor-deposited, a ferromagnetic yoke for influencing the vapor deposition of the coating material to be vapor-deposited and at least one permanent-magnetic body for influencing the vapor deposition of the coating material to be vapor-deposited. The ferromagnetic yoke is disposed in contact with the target. The permanent-magnetic body is fastened to the target by the ferromagnetic yoke.

The present invention relates to an arc evaporation coating source, which has a target of a coating material to be vapor-deposited, a ferromagnetic yoke for influencing the vapor deposition of the coating material to be vapor-deposited and at least one permanent-magnetic body for influencing the vapor deposition of the coating material to be vapor-deposited.

Methods of physical vapor deposition are widely used in technology for producing greatly varying layers. Applications range from the production of wear-resistant and corrosion-resistant coatings for greatly varying substrate materials to the production of coated material composites, in particular in the semiconductor and electronics industry. Because of this broad range of applications, various coating materials have to be deposited.

Various techniques are used for physical vapor deposition, e.g. vapor deposition, cathode sputtering (sputter deposition) or arc evaporation (or: electric arc vapor deposition, cathodic arc deposition or arc source vapor deposition technique).

In the method of cathode sputtering, a plasma is generated in a chamber by means of a working gas, e.g. argon. Ions of the working gas are accelerated toward a target formed from coating material and knock out of the target particles of the coating material that go over into the vapor phase and, from this phase, are deposited on a substrate to be coated. It is known in the method of cathode sputtering to form a magnetic field over the active surface of the target in order to assist the process. The magnetic field thereby increases the plasma density in the proximity of the active surface of the target, and therefore leads to increased removal of the coating material. Such a method is referred to as magnetron cathode sputtering (magnetron sputter deposition).

The method of arc evaporation differs fundamentally from the method of cathode sputtering described above. Arc evaporation is used inter alia for carbide coatings of tools and machine parts and for layers in the decorative field of application. Arc evaporation uses an arc discharge, which is ignited between the coating material provided as the target, as a cathode, and an anode. The resultant high-current/low-voltage arc (hereinafter arc) is produced spontaneously by way of the free charge carriers of the cathode and a higher partial pressure, so that an arc discharge can be maintained even under a high vacuum. Depending on the design of the technique used, the position of the arc moves either more or less randomly (so called random-arc technique) or in a controlled manner (so-called steered-arc technique) over the surface of the cathode, a high energy input into the surface of the target occurring in a very small area (at so-called spots). This high energy input leads locally to vaporization of the coating material on the surface of the target. The region of a spot consists of liquid droplets of the coating material, coating material vapor and generated ions of the coating material. The target is only transformed into the molten state in very small areas and can therefore be operated as a vapor deposition source with a relatively high coating rate in any position. The ionizing of the coating material vapor is of great significance for the resultant properties of the layer of coating material deposited on the substrate to be coated. In the case of coating materials with a high vapor pressure, typically about 25% of the vapor particles are in the ionized state and, in the case of coating materials with a low vapor pressure, typically between 50% and 100% of the vapor particles are in the ionized state. Consequently, reactive ion plating does not require any additional ionizing devices in the facility. The fundamental parameters in the technique of arc evaporation are the arc voltage and the arc current, which are influenced by further parameters, such as in particular the material of the target, an existing reactive gas and the given working pressure. Typical operating conditions for arc evaporation are, for example, an arc voltage of between 15 V and 30 V and an arc current of between 50 A and 150 A.

In arc evaporation, the speed of the movement of the arc on the surface of the target determines the quantity of the molten material at the corresponding spot. The lower the speed, the larger the quantity of coating material accelerated out of the spot toward the substrate to be coated. A low speed therefore leads to undesired spatter or macroparticles in the layer growing on the substrate. The speed of the movement of the arc that is achieved is dependent on the coating material of the target. A reduced electrical conductivity of the coating material leads to a reduction in the speed of the arc. If the speed of the arc on the surface of the target is too low, i.e. there is an excessively long dwell time on one spot, local thermal overloading of the target and severe contamination of the layer growing on the substrate with undesired spatter or macroparticles are the result. Premature unusability of the target can also occur because of macroscopic melted areas on the surface. It has therefore so far scarcely been possible to use in particular materials with a poor thermal shock resistance for arc evaporation.

The speed of the position of the arc, and therefore the spot size, can be influenced by magnetic fields. The higher the magnetic field strength, the faster the arc moves. In facilities for arc evaporation, it is known to provide electromagnets or permanent magnets behind a cooled support for the target in order to influence the speed of the arc.

WO 2011/127504 A1 describes a coating source for physical vapor phase deposition with a powder-metallurgically produced target of coating material to be vapor-deposited and at least one ferromagnetic region incorporated in the target in a powder-metallurgical production process and securely connected to the target.

It is the object of the present invention to provide an arc evaporation coating source that makes a particularly stable coating process possible even in the case of a relatively high-melting coating material, ceramic coating material with poor thermal shock resistance and magnetic coating material.

The object is achieved by an arc evaporation coating source as claimed in claim 1. Advantageous developments are specified in the dependent claims.

The arc evaporation coating source has a target of a coating material to be vapor-deposited, a ferromagnetic yoke for influencing the vapor deposition of the coating material to be vapor-deposited, and at least one permanent-magnetic body for influencing the vapor deposition of the coating material to be vapor-deposited. The ferromagnetic yoke is arranged in contact with the target. The permanent-magnetic body is fastened to the target by way of the ferromagnetic yoke.

In the present description, a target is understood as meaning the region of a coating source that is formed from the coating material to be vapor-deposited. The fastening of the permanent-magnetic body to the target by way of the ferromagnetic yoke makes it possible to provide a particularly stable coating process, even in the case of high-melting materials as the coating material, in the case of ceramic coating material with poor thermal shock resistance and in the case of magnetic coating material, by the arrangement of the ferromagnetic yoke in contact with the target. It is also preferred that the permanent-magnetic body is in direct contact with the target. In particular, the coating material may have a melting point that lies above the Curie temperature of the material of the permanent-magnetic body, and the target may be produced powder-metallurgically at relatively high temperatures without destroying the permanent magnetization of the permanent-magnetic body, since the permanent-magnetic body can be fastened to the target subsequently by way of the ferromagnetic yoke, which would not be possible in this case if the permanent-magnetic body were introduced into the material of the target directly by powder-metallurgical means. Furthermore, a particularly compact form of the arc evaporation coating source is provided, a form in which the ferromagnetic yoke and the at least one permanent-magnetic body can be arranged very close to the active surface of the target in an easy and low-cost way. The combination of the ferromagnetic yoke with the at least one permanent-magnetic body also allows the magnetic field on the active surface of the target to be predetermined very reliably. It is possible for example for just one permanent-magnetic body to be provided, or the arc evaporation coating source may for example also have a number of permanent-magnetic bodies. Apart from the ferromagnetic yoke, further ferromagnetic components or regions may also be additionally provided. It is preferred that the ferromagnetic yoke can be formed in one piece, but it may also have a plurality of separate elements. The design according to the invention makes it possible also to produce arc evaporation coating sources with targets of ceramic or metal-ceramic materials by for example hot pressing or so-called spark plasma sintering (SPS), in which methods permanent-magnetic bodies would lose their magnetization because of the high temperatures involved. With the arc evaporation coating source according to the invention, magnetic materials can also be vapor-deposited by means of an arc in continuous operation in an arc evaporation coating facility without the materials showing any undesired crack formation.

According to a development, the ferromagnetic yoke and the target are connected to one another by way of a mechanical connection. In this case, reuse of the ferromagnetic yoke and the permanent-magnetic body once the target has been used up is made possible in a particularly advantageous way. A mechanical connection is understood here as meaning a releasable non-positive and/or positive connection. The mechanical connection may comprise in particular a threaded connection, a bayonet connection or a similar connection. It is preferred that the ferromagnetic yoke and the target are connected to one another by way of a threaded connection. In this case, particularly easy and low-cost installation of the arc evaporation coating source is made possible.

According to a development, the target is provided with an external thread, which interacts with an internal thread provided on the yoke. In this case, the target can be connected to the yoke and the permanent-magnetic body in an easy and low-cost way by screwing into the internal thread of the ferromagnetic yoke.

It is preferred that the ferromagnetic yoke is arranged on a rear side of the target. According to a development, the ferromagnetic yoke surrounds a rear side of the target substantially in the form of a pot. In this case, the magnetic field on the active surface of the target can be set particularly reliably. In particular, the resultant magnetic field on the active surface of the target can in this case be modeled or changed in the desired way by minor changes to the form of the yoke and the form and thickness of the permanent-magnetic body.

According to a development, the permanent-magnetic body is accommodated in the ferromagnetic yoke on a side of the yoke that is facing the target. In this case, the permanent-magnetic body can be fastened to the target particularly reliably and the magnetic field of the permanent-magnetic body can be modeled in the desired way by the yoke.

According to a development, the permanent-magnetic body takes the form of a ring. In this case, a particularly symmetrical formation of the magnetic field on the active surface of the target is made possible. Depending on the form of the target, the permanent-magnetic body may for example have a substantially circular ring form, a substantially oval ring form or else an angular ring form.

According to a development, the yoke has a connecting portion for the mechanical fastening to a cooled support of an arc evaporation coating facility. In this case, the arc evaporation coating source can be fastened in the coating facility in a very space-saving manner without any further components. According to a development, the connecting portion has a thread. Depending on the design of the coating facility, the thread may for example be formed as an internal thread for interaction with an external thread of the coating facility or for example as an external thread for interaction with an internal thread of the coating facility.

Further advantages and expedient aspects of the invention emerge from the following description of exemplary embodiments with reference to the accompanying figures.

Of the figures:

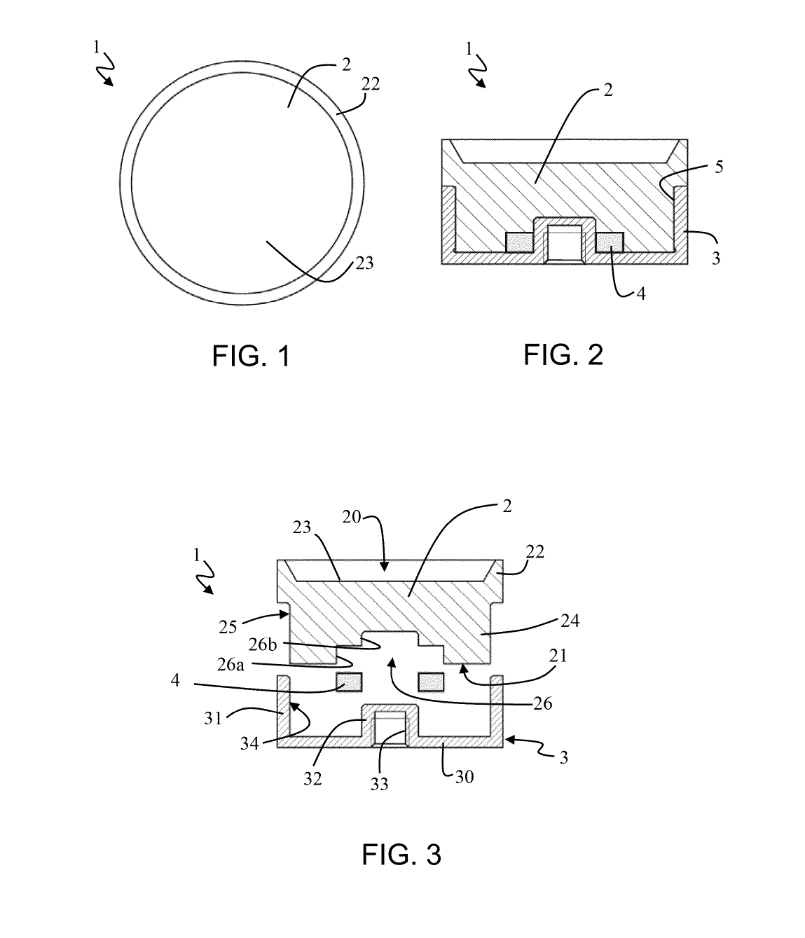

FIG. 1: shows a schematic plan view of an arc evaporation coating source according to one embodiment;

FIG. 2: shows a schematic sectional representation of the arc evaporation coating source from FIG. 1;

FIG. 3: shows a schematic exploded sectional representation to explain the individual components of the arc evaporation coating source;

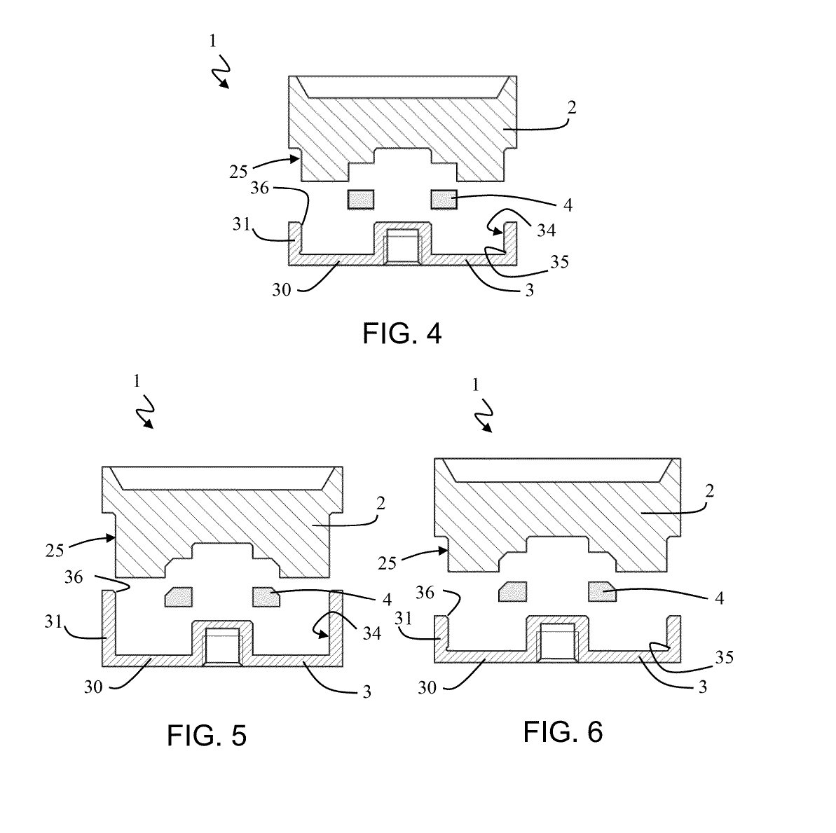

FIG. 4: shows a schematic exploded sectional representation of an arc evaporation coating source according to a first modification;

FIG. 5: shows a schematic exploded sectional representation of an arc evaporation coating source according to a second modification and

FIG. 6: shows a schematic exploded sectional representation of an arc evaporation coating source according to a further modification.

An embodiment is described in more detail below with reference to FIG. 1 and FIG. 2, possible modifications also being described with reference to FIG. 3 to FIG. 6 and the same designations being used in each case for the components that correspond.

In the case of the first embodiment, the arc evaporation coating source 1 has a substantially round form in plan view, as can be seen in FIG. 1. Although arc evaporation coating sources 1 with a substantially round form are described in each case with respect to the exemplary embodiment and modifications thereof, other forms are also possible, in particular also oval or elongated rectangular forms.

The arc evaporation coating source 1 has a target 2, which consists of the coating material to be vapor-deposited. In the case of the exemplary embodiment represented, the target 2 has a substantially cylindrical form with a front side 20 and a rear side 21. The front side 20 is formed as an active surface, on which the arc moves during the operation of the arc evaporation coating source 1 in an arc evaporation coating facility and the vapor deposition of the coating material takes place. The front side 20 has a substantially planar face 23, which is surrounded by a peripheral edge 22, which protrudes from the planar face 23 on the front side 20. On the outer side, the edge 22 is delimited by a substantially cylindrical surface. The edge 22 has an inside diameter that widens slightly from the planar face 23, so that the edge 22 tapers with increasing distance from the planar face 23.

Although a design in which the target 2 has the edge 22 described above is shown in the case of the exemplary embodiment, it is also possible for example that the target 2 has a completely flat front side 20 without such an edge 22. Still further different designs of the front side 20 are also possible.

On the rear side of the substantially cylindrical outside diameter of the edge 22, the target 2 is provided in a region 24 which adjoins the rear side 21 and which has an outside diameter that is somewhat smaller than the outside diameter in the region of the edge 22, so that a peripheral step is formed in the outer side of the target 2.

In the region 24 adjoining the rear side 21, in the case of the embodiment the target 2 likewise has a substantially cylindrical outside diameter. In this region 24, the target 2 is provided with an external thread 25, the function of which is subsequently described in still more detail.

Formed in a central region in the rear side 21 is a recess 26, which in the case of the exemplary embodiment represented has a two-stage design with a first portion 26a of a greater cross section and an adjoining second portion 26b of a smaller cross section. Although such a two-stage design is shown in the case of the exemplary embodiment, other designs are also possible, for example the recess 26 may also be formed as a simple depression with only a first portion.

The target 2 may be produced in particular in a powder-metallurgical production process from one or more starting powders by compacting in a press and subsequent sintering, it also being possible in particular for the starting powder or powders to comprise one or more components with a very high melting point. The target 2 may in this case also be formed in particular from a metal-ceramic or ceramic material as the coating material.

In the case of the exemplary embodiment represented, the external thread 25 may for example be incorporated in the coating material directly during the powder-metallurgical production process, for example by pressing into the corresponding form or by machining of the blank before the sintering, or else the external thread 25 may be produced by machining after the sintering.

As can be seen in particular in FIG. 2 and FIG. 3, the arc evaporation coating source 1 also has a ferromagnetic yoke 3, which in the case of the exemplary embodiment may be formed for example by steel. However, other ferromagnetic materials are also possible for example. The ferromagnetic yoke 3 has a pot-shaped form with a bottom region 30 and a side wall 31 extending from the bottom region 30 in a peripheral manner upwardly, i.e. in the direction of the active surface of the target 2. In a central portion, the bottom region 30 is provided with a projection 32, which extends from the bottom region 30 in the direction of the target 2. On the side facing the target 2, the bottom region 30 consequently has a substantially annular surface surrounding the projection 32.

The ferromagnetic yoke 3 is provided with a connecting portion for the mechanical fastening to a cooled support of an arc evaporation coating facility. In the case of the exemplary embodiment, an internal thread 33 that is adapted to interact with a corresponding external thread on a cooled support of the arc evaporation coating facility is formed in the projection 32, from the rear side of the ferromagnetic yoke 3. Although in the case of the exemplary embodiment such an internal thread 33 is provided on the yoke, it is also possible for example to provide a differently formed connecting portion on the ferromagnetic yoke 3, for example a projection with an external thread projecting from the rear side. Although in the present case a description is given of an exemplary embodiment in which the arc evaporation coating source 1 is designed to be fastened by a thread connection in the arc evaporation coating facility, other methods of connection are also possible. For example, the arc evaporation coating source 1 may also be designed to be connected to the arc evaporation coating facility by way of a collar or by way of a bayonet fastener or the like.

The ferromagnetic yoke 3 has an internal thread 34, which is designed for the purpose of interacting with the external thread 25 of the target 2 to form a threaded connection. As can be seen in particular in FIG. 2, the ferromagnetic yoke 3 and the target 2 are consequently connected to one another by way of a mechanical connection 5, which in the case of the exemplary embodiment represented is formed by the threaded connection. As can be seen in FIG. 2, the outside diameter of the side wall 31 of the ferromagnetic yoke 3 is dimensioned in such a way that it corresponds to the outside diameter of the target 2 in the region of the active surface, so that the ferromagnetic yoke 3 adjoins the target 2 flush in the screwed-together state.

The arc evaporation coating source 1 also has at least one permanent-magnetic body 4. In the case of the exemplary embodiment, the permanent-magnetic body 4 is formed by a ring, which is placed into the ferromagnetic yoke 3 before the forming of the mechanical connection between the ferromagnetic yoke 3 and the target 2. In the case of the exemplary embodiment, the permanent-magnetic body 4 is designed in such a way that it can be placed into the ferromagnetic yoke 3 such that it surrounds the projection 32 at the bottom region 30 of the ferromagnetic yoke 3 in a substantially annular manner and is kept centered by the projection 32.

The outer circumference of the permanent-magnetic body 4 and the recess 26 in the target 2 are adapted to one another in such a way that the permanent-magnetic body 4 is accommodated in the recess 26. In the case of the exemplary embodiment represented, the permanent-magnetic body 4 is accommodated in the first portion 26a of the recess 26 and the projection 32 extends into the second portion 26b of the recess 26. Although in the case of the exemplary embodiment only one permanent-magnetic body 4 is represented, a plurality of permanent-magnetic bodies 4 may also be provided. Furthermore, the permanent-magnetic bodies 4 may also take a different form.

As can be seen in particular in FIG. 2, the target 2, the ferromagnetic yoke 3 and the permanent-magnetic body 4 are made to match one another in form in such a way that, in an assembled state of the arc evaporation coating source 1, the target 2, the ferromagnetic yoke 3 and the permanent-magnetic body 4 lie securely against one another. Consequently, the arc evaporation coating source 1 has a very compact structure.

In order to provide the best possible electrical and thermal contacting between the rear side 21 of the target 2 and the bottom region 30 of the ferromagnetic yoke 3, between the target 2 and the bottom region 30 of the ferromagnetic yoke 3 there may also be arranged a sheet of a material of high electrical and thermal conductivity, for example a thin graphite foil, which during the forming of the mechanical connection between the target 2 and the ferromagnetic yoke 3 is clamped in between them. The sheet may have in particular a substantially annular form, which is adapted to the annular bottom region 30 around the projection 32.

In the case of the arc evaporation coating source 1 described, the resultant magnetic field on the active surface of the target 2 may be changed or adapted in an easy way by slight geometrical adaptations of the form of the target 2, of the ferromagnetic yoke 3 and/or of the permanent-magnetic body 4, as schematically represented in FIG. 4 to FIG. 6.

As schematically represented in FIG. 4, the height of the side wall 31 of the ferromagnetic yoke 3 may be changed to change the resultant magnetic field. Furthermore, the wall thickness of the side wall 31 of the ferromagnetic yoke 3 may also be changed to change the resultant magnetic field.

As can also be seen in FIG. 4, it is preferred that a relief groove 35 can be provided on the inner side of the side wall 31 underneath the internal thread 34.

As can be seen in FIG. 4, the free end of the side wall 31 of the ferromagnetic yoke has on the inner side a rounded design with a predetermined radius of curvature 36. The resultant magnetic field can likewise be significantly influenced by increasing or reducing the radius of curvature 36.

As schematically represented in FIG. 5 and FIG. 6, the form of the permanent-magnetic body 4 can also be changed in order to change the resultant magnetic field. In FIGS. 5 and 6, the ferromagnetic body 4 likewise has a substantially annular form, although the outer circumference of the ferromagnetic body 4 is formed in a somewhat flattened or rounded manner on the side facing the target 2. In particular, the possibilities described for changing the geometrical forms of the side wall 31 of the ferromagnetic yoke 3 and of the permanent-magnetic body 4 can be combined with one another to provide a desired resultant magnetic field.

According to a development, the described arc evaporation coating source 1 can also be thermally coupled even better to the cooled support of an arc evaporation coating facility by casting with a backing material of high thermal conductivity, such as for example Cu or a Cu alloy, so that coating materials with very low thermal shock resistance can also be vapor-deposited in an arc evaporation coating facility by means of an arc.

Consequently, a description has been given of an embodiment that makes it possible to provide a very high magnetic field density on the surface of the target of an arc evaporation coating source. In this way, the ignition properties and the stability of the arc during a coating process in arc evaporation are significantly improved. In the case of metallic targets, a reduction in the emission of spatter and droplets is achieved in this way. In the case of targets of metal-ceramic material or ceramic material, the greater speed in the movement of the arc that is achieved and the possibility of directing the movement, and consequently the removal of the coating material, into desired paths mean that the local energy input at the spot is reduced and disadvantages caused by low electrical conductivity and low thermal shock resistance of the coating material are compensated. The ferromagnetic yoke 3 and the at least one permanent-magnetic body 4 may be arranged in such a way that the removal process or the removal profile of the coating material can be controlled. Furthermore, a direct deposition of ferromagnetic coating materials by means of arc evaporation is also made possible.

The ferromagnetic yoke 3 and the at least one permanent-magnetic region 4 can for example be optimized such that the desired magnetic fields are set with great accuracy in conjunction with external magnetic fields provided in the coating facility in the region of the target that is near the surface. It is possible thereby to provide a specific weakening and/or strengthening of facility-side magnetic fields with local resolution. The magnetic regions may also be formed for example in such a way that certain regions are shielded for the coating process, so that no appreciable removal takes place there. Furthermore, certain regions of the target may be protected by the described design from contamination, in that for example an undesired coating of the target with for example ceramic nitride or oxide layers is avoided by specifically configuring the resultant magnetic fields. The paths of movement of the arc on the active surface of the target can be predetermined. This makes it possible for example to use segmented targets, which either can only be produced with small dimensions on account of their production technology or have different material compositions in different regions, for depositing layers with a desired chemical composition.

1-10. (canceled)

11. An arc evaporation coating source, comprising:
a target made of a coating material to be vapor-deposited;
a ferromagnetic yoke for influencing a vapor deposition of said coating material to be vapor-deposited, said ferromagnetic yoke being disposed in contact with said target; and
at least one permanent-magnetic body for influencing said vapor deposition of said coating material to be vapor-deposited, said permanent-magnet body being fastened to said target by said ferromagnetic yoke.

12. The arc evaporation coating source according to claim 11, wherein said ferromagnetic yoke and said target are connected to one another by a mechanical connection.

13. The arc evaporation coating source according to claim 11, wherein said ferromagnetic yoke and said target are connected to one another by a threaded connection.

14. The arc evaporation coating source according to claim 11, wherein said target has an external thread, said ferromagnetic yoke has an internal thread, and said external and internal threads interact with one another.

15. The arc evaporation coating source according to claim 11, wherein said target has a rear side, and said ferromagnetic yoke is disposed on said rear side.

16. The arc evaporation coating source according to claim 11, wherein said target has a rear side, and said ferromagnetic yoke is substantially pot-shaped and surrounds said rear side.

17. The arc evaporation coating source according to claim 11, wherein said ferromagnetic yoke has a side facing said target, and said permanent-magnet body is accommodated in said ferromagnetic yoke on said side of said ferromagnetic yoke.

18. The arc evaporation coating source according to claim 11, wherein said permanent-magnetic body is ring-shaped.

19. The arc evaporation coating source according to claim 11, wherein said ferromagnetic yoke has a connecting portion for mechanical fastening to a cooled support of an arc evaporation coating facility.

20. The arc evaporation coating source according to claim 19, wherein said connecting portion has a thread.
